(19) United States
(12) Patent Application Publication
(10) Pub. No.: US 2025/0104967 A1
(43) Pub. Date: Mar. 27, 2025

(54) SUBSTRATE PROCESSING APPARATUS AND SUBSTRATE PROCESSING METHOD USING THE SAME

(71) Applicant: Samsung Electronics Co., Ltd., Suwon-si (KR)

(72) Inventors: CHANGBAE PARK, Suwon-si (KR); KI-IL KIM, Suwon-si (KR); Jae Sik AN, Suwon-si (KR); SUNTAEK LIM, Suwon-si (KR)

(21) Appl. No.: 18/596,976

(22) Filed: Mar. 6, 2024

(30) Foreign Application Priority Data
Sep. 26, 2023 (KR) 10-2023-0129181

(51) Int. Cl. H01J 37/32; H01L 21/3065

(52) U.S. Cl. CPC H01J 37/32082; H01J 2237/327; H01L 21/3065

(57) ABSTRACT

Disclosed are substrate processing apparatuses and substrate processing methods using the same. The substrate processing apparatus comprises a process chamber that provides a process space; a stage that supports a substrate, a gas spray device in the process space and upwardly spaced apart from the stage, a dielectric layer in the process space and upwardly spaced apart from the stage, a piezoelectric element that has a connection with and vibrates the dielectric layer, and a piezo power source that supplies the piezoelectric element with an alternating electric power.

### CROSS-REFERENCE TO RELATED APPLICATION

This U.S. nonprovisional application claims priority under 35 U.S.C. § 119 to Korean Patent Application No. 10-2023-0129181, filed on Sep. 26, 2023, in the Korean Intellectual Property Office, the disclosure of which is hereby incorporated by reference in its entirety.

### BACKGROUND

The present inventive concepts relate to a substrate processing apparatus and a substrate processing method using the same, and more particularly, to a substrate processing apparatus configured to vibrate a dielectric plate to change a volume of a process space in which a plasma is produced and a substrate processing method using the same.

A semiconductor device may be fabricated through various processes. An etching process is a way of selectively removing unnecessary portions by using a liquid or a gas etchant. The etching process is classified into a dry etching process and a wet etching process. The dry etching process is a way of using a reactive gas or ion to remove a certain portion, and the wet etching process is a way of etching through a chemical reaction with a solution.

The dry etching process is typically performed by generating plasma, and when the plasma is generated in a process chamber, there are generated ions, electrons, and radicals or reactive gases. In general, the ions induce an anisotropic reaction, while the radicals induce an isotropic reaction.

### SUMMARY

Some embodiments of the present inventive concepts provide a substrate processing apparatus capable of accelerating radicals to improve reactions occurring at deep portions of patterns and a substrate processing method using the same.

Some embodiments of the present inventive concepts provide a substrate processing apparatus capable of accelerating radicals to achieve a process with high aspect ratio and high etch selectivity in a semiconductor etching process and a substrate processing method using the same.

Some embodiments of the present inventive concepts provide a substrate processing apparatus capable of using a piezoelectric element and a dielectric plate to change a volume of a process space in which plasma is produced and a substrate processing method using the same.

Some embodiments of the present inventive concepts provide a substrate processing apparatus capable of changing a volume of a process space to accelerate radicals to accomplish a selective etching process and a substrate processing method using the same.

The object of the present inventive concepts is not limited to the mentioned above, and other objects which have not been mentioned above will be clearly understood to those skilled in the art from the following description.

According to some embodiments of the present inventive concepts, a substrate processing apparatus may comprise: a process chamber configured to provide a process space; a stage configured to support a substrate; a gas spray device in the process space and upwardly spaced apart from the stage; a dielectric layer in the process space and upwardly spaced apart from the stage; a piezoelectric element connected with the dielectric layer and configured to vibrate the dielectric layer; and a piezo power source configured to supply the piezoelectric element with an alternating electric power.

According to some embodiments of the present inventive concepts, a substrate processing apparatus may comprise: a process chamber configured to provide a process space; a stage disposed in the process substrate and configured to support a substrate; a gas spray device in the process space and upwardly spaced apart from the stage; a dielectric layer disposed in the process space and having a level higher than a level of a lower end of the gas spray device; a piezoelectric element connected to and positioned on the dielectric layer; and a piezo power source configured to supply the piezoelectric element with an alternating electric power. The dielectric layer may include: a film body; and a coating layer which surrounds the film body and includes a dielectric material.

According to some embodiments of the present inventive concepts, a substrate processing method may comprise: placing a substrate in a substrate processing apparatus; and processing the substrate. The substrate processing apparatus may include: a process chamber providing a process space; a gas spray device disposed in the process space and configured to spray a gas into the process space; a dielectric layer which connects the gas spray device and the process chamber to each other; a piezoelectric element which is connected to the dielectric layer and is capable of vibrating; and a piezo power source which supplies the piezoelectric element with an alternating electric power to vibrate the piezoelectric element. The step of processing the substrate may include: generating plasma; allowing the piezo power source to vibrate the piezoelectric element; and using the vibration of the piezoelectric element to vibrate the dielectric layer.

Details of other example embodiments are included in the description and drawings.

### BRIEF DESCRIPTION OF DRAWINGS

FIG. 1 illustrates a front view showing a substrate processing apparatus according to some example embodiments of the present inventive concepts.

FIG. 2 illustrates an enlarged front view partially showing a substrate processing apparatus according to some example embodiments of the present inventive concepts.

FIG. 3 illustrates a front view showing a substrate processing apparatus according to some example embodiments of the present inventive concepts.

FIG. 4 illustrates an enlarged front view partially showing a substrate processing apparatus according to some example embodiments of the present inventive concepts.

FIG. 5 illustrates an enlarged front view partially showing a substrate processing apparatus according to some example embodiments of the present inventive concepts.

FIG. 6 illustrates graphs showing currents of a piezo power source, a lower RF power source, and an upper power source according to some example embodiments of the present inventive concepts.

FIG. 7 illustrates graphs showing currents of a piezo power source, a lower RF power source, and an upper power source according to some example embodiments of the present inventive concepts.

FIG. 8 illustrates a perspective view showing a dielectric layer according to some example embodiments of the present inventive concepts.

FIG. 9 illustrates a front view showing a dielectric layer according to some example embodiments of the present inventive concepts.

FIG. 10 illustrates a flow chart showing a substrate processing method according to some example embodiments of the present inventive concepts.

### DETAILED DESCRIPTION OF EMBODIMENTS

The following will now describe some example embodiments of the present inventive concepts with reference to the accompanying drawings. Like reference numerals indicate like components throughout the description.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called an upward direction, and a direction opposite to the first direction D1 may be called a downward direction. In addition, each of the second direction D2 and the third direction D3 may be called a horizontal direction. The first direction D1, the second direction D2, and the third direction D3 may be perpendicular to one another.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

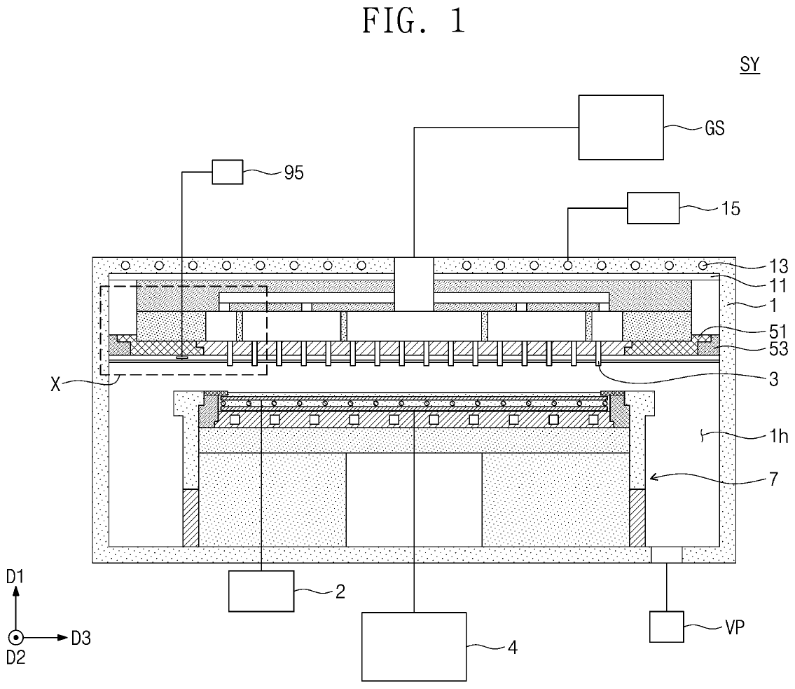

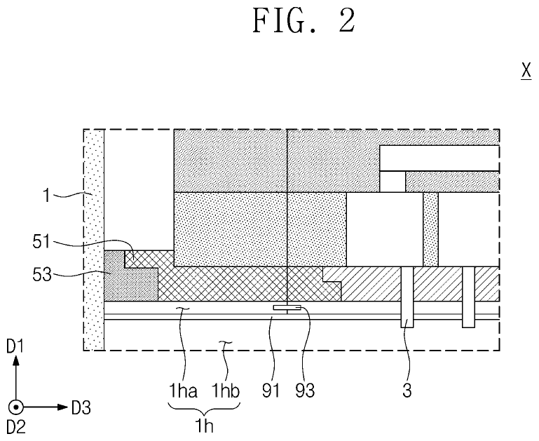

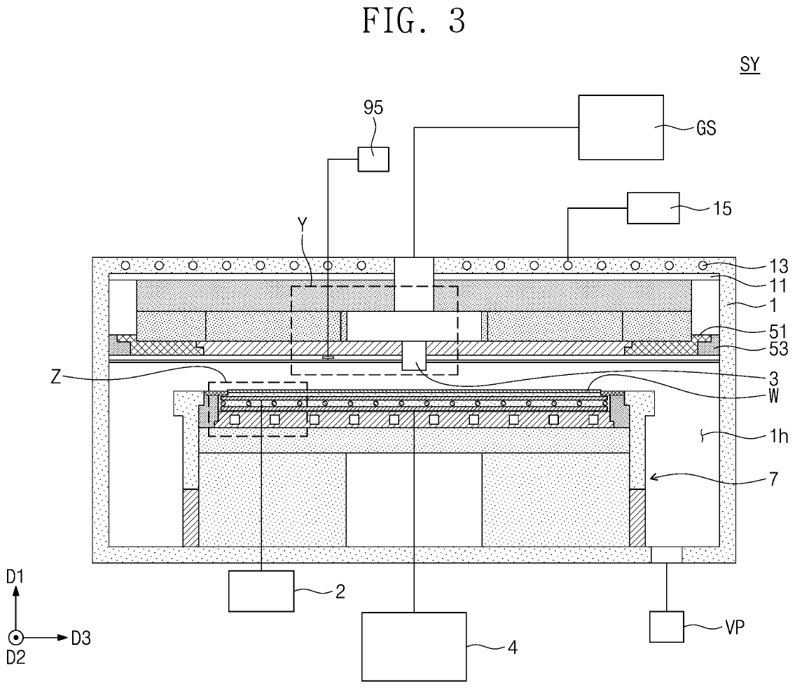

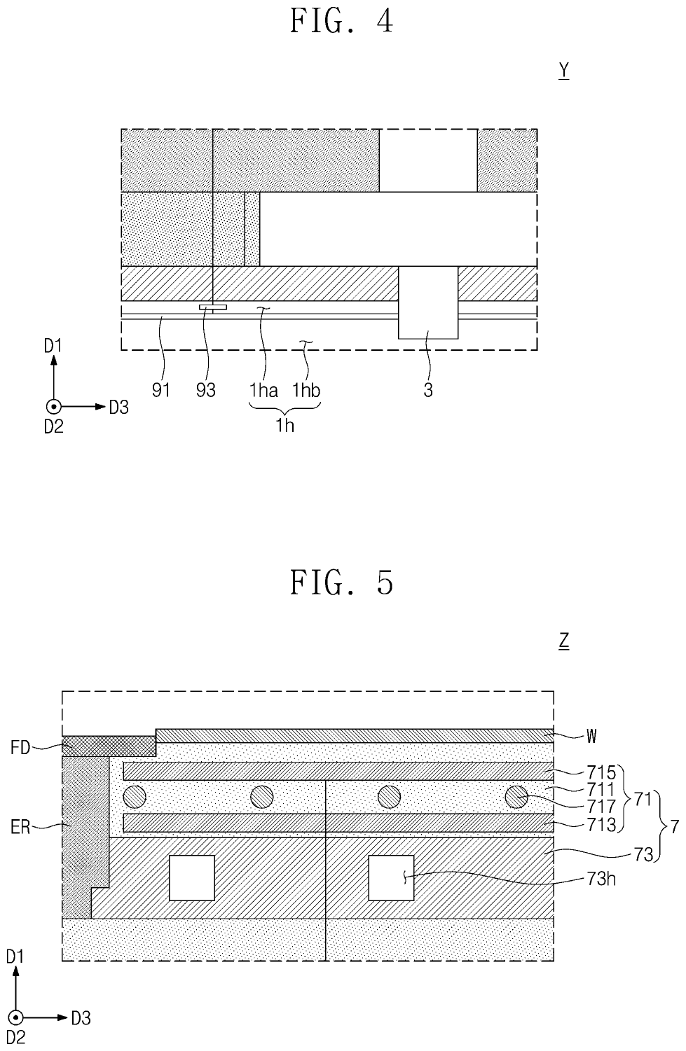

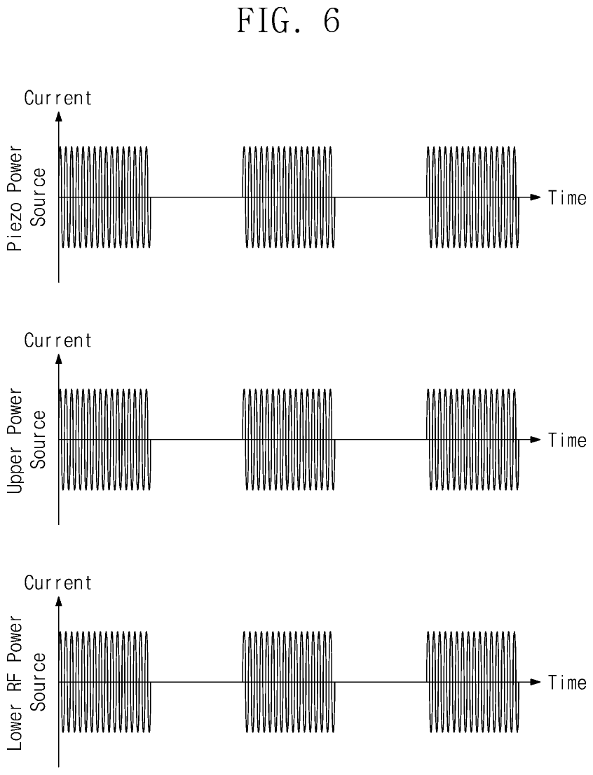

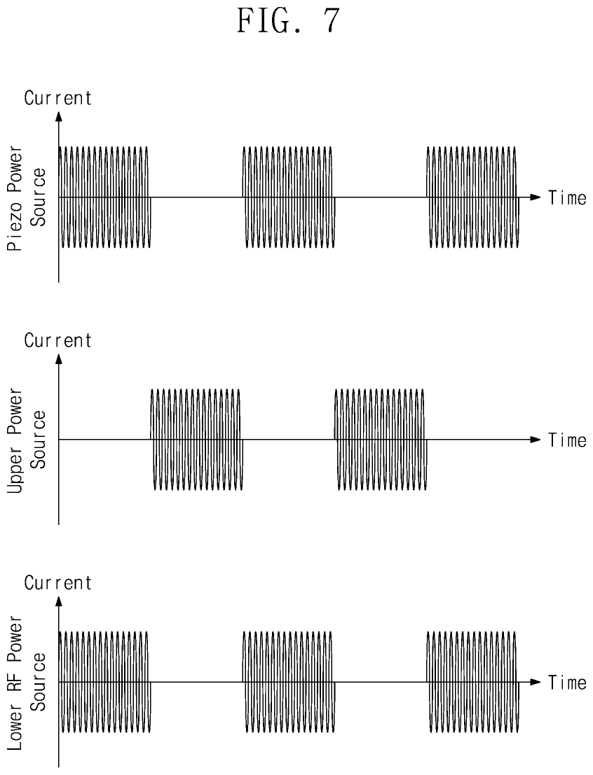

FIG. 1 illustrates a front view showing a substrate processing apparatus SY according to some example embodiments of the present inventive concepts. FIG. 2 illustrates an enlarged front view partially showing a substrate processing apparatus SY according to some example embodiments of the present inventive concepts. FIG. 3 illustrates a front view showing a substrate processing apparatus SY according to some example embodiments of the present inventive concepts. FIG. 4 illustrates an enlarged front view partially showing a substrate processing apparatus SY according to some example embodiments of the present inventive concepts. FIG. 5 illustrates an enlarged front view partially showing a substrate processing apparatus SY according to some example embodiments of the present inventive concepts. FIG. 6 illustrates graphs showing currents of a piezo power source 95, a lower RF power source 4, and an upper power source 15 according to some example embodiments of the present inventive concepts. FIG. 7 illustrates graphs showing currents of a piezo power source 95, a lower RF power source 4, and an upper power source 15 according to some example embodiments of the present inventive concepts.

Referring to FIGS. 1 and 2, the substrate processing apparatus SY may be provided. The substrate processing apparatus SY may be a device used for an etching process and/or a deposition process performed on a substrate W. The present inventive concepts, however, are not limited thereto. In this description, the term “substrate W” may mean a silicon (Si) wafer, but the present inventive concepts are not limited thereto. The substrate processing apparatus SY may use plasma to process the substrate W. The substrate processing apparatus SY may use various ways to generate plasma. For example, the substrate processing apparatus SY may be a capacitively coupled plasma (CCP) apparatus and/or an inductively coupled plasma (ICP) apparatus. The substrate processing apparatus SY may include a process chamber 1, a stage 7, a gas spray device 3, an outer ring 51, a heating liner ring 53, a direct-current (DC) power source 2, a lower radio-frequency (RF) power source 4, a vacuum pump VP, a gas supply device GS, a dielectric layer 91, a piezoelectric element 93, and a piezo power source 95.

The process chamber 1 may provide a process space 1h. A process of the substrate W may be performed in the process space 1h. The process space 1h may be isolated from an external space. While a process is performed on the substrate W, the process space 1h may be substantially in a vacuum state. Alternatively, plasma may be generated in the process space 1h. The plasma may include ions, electrons, and radicals. The radicals may be neutral. The radicals may include an isotropic reaction with the substrate W. The radicals may be in an unstable state. The radicals may easily react with the substrate W. The ions may have charges. An electric field may cause the ions to induce an anisotropic reaction with the substrate W. The process space 1h may have a cylindrical shape. The process chamber 1 may have a cylindrical shape, but the present inventive concepts are not limited thereto.

The stage 7 may be positioned in the process chamber 1. For example, the stage 7 may be positioned in the process space 1h. The stage 7 may support and/or hold the substrate W. A substrate process may be performed on the substrate W in a state where the substrate W is placed on the stage 7. The stage 7 will be further discussed in detail below.

The gas spray device 3 may spray a gas into the process space 1h. For example, a gas supplied from the gas supply device GS may be uniformly sprayed through the gas spray device 3 into the process space 1h. The gas spray device 3 may be disposed in the process chamber 1. For example, the gas spray device 3 may be positioned in the process space 1h. The gas spray device 3 may be disposed upwardly spaced apart from the stage 7. For example, the gas spray device 3 may be disposed above the stage 7, and may be facing the stage 7. The gas spray device 3 may have a showerhead shape as shown in FIG. 1. The gas spray device 3 may have a nozzle shape as shown in FIG. 3. The present inventive concepts, however, are not limited thereto, and the gas spray device 3 may have any other suitable shape capable of uniformly spraying a gas into the process space 1h.

The outer ring 51 may surround the gas spray device 3. For example, outside the gas spray device 3, the outer ring 51 may surround the gas spray device 3. The outer ring 51 may be in contact with the gas spray device 3. For example, the outer ring 51 may contact side surfaces of the gas spray device 3.

The heating liner ring 53 may surround the outer ring 51. For example, outside the outer ring 51, the heating liner ring 53 may surround the outer ring 51. The heating liner ring 53 may support the outer ring 51. For example, the heating liner ring 53 may contact side surfaces of the outer ring 51. The heating liner ring 53 may include aluminum (Al) and yttrium oxide (Y₂O₃). For example, yttrium oxide (Y₂O₃) may be coated on aluminum (Al) to form the heating liner ring 53.

The DC power source 2 may apply a DC power to the stage 7. The DC power applied from the DC power source 2 may rigidly place the substrate W on a certain position on the stage 7. For example, the DC power source 2 may apply the DC power to stage 7 to hold the substrate W firmly in place on the stage 7.

The lower RF power source 4 may supply the stage 7 with an alternating electric power. The lower RF power source 4 may be electrically connected to the stage 7. The lower RF power source 4 may supply the stage 7 with a RF electric power. The RF electric power may have a frequency of about 12 MHz to about 14 MHz. For example, the RF electric power may have a frequency of about 13.5 MHz. The lower RF power source 4 may supply the stage 7 with an alternating current. The lower RF power source 4 may control the plasma in the process space 1h. For example, the lower RF power source 4 may adjust concentration of the plasma, pressure of the plasma, and energy of particles.

The vacuum pump VP may be connected to the process space 1h. The vacuum pump VP may apply a vacuum pressure to the process space 1h during a process performed on the substrate W.

The gas supply device GS may supply the process space 1h with gas. The gas supply device GS may include a gas tank, a compressor, and a valve. The plasma may be generated from a portion of gas supplied from the gas supply device GS to the process space 1h.

The substrate processing apparatus SY may further include a focus ring FD. The focus ring FD may control the plasma on an edge of the substrate W. For example, a height and angle of the focus ring FD may be adjusted to control a concentration of the plasma on the substrate W. The focus ring FD may have an annular shape. The focus ring FD may be positioned on the stage 7. The focus ring FD may surround the substrate W. The focus ring FD may support the substrate W. In some embodiments, the focus ring FD may contact a side surface of the substrate W.

The substrate processing apparatus SY may further include a dielectric plate 11, a coil 13, and an upper power source 15. The dielectric plate 11 may be positioned on the gas spray device 3. The coil 13 may be positioned on the dielectric plate 11. The coil 13 may be positioned on the gas spray device 3. The coil 13 may be electrically connected to the upper power source 15. The upper power source 15 may supply the coil 13 with an alternating electric power. As the alternating electric power is supplied from the upper power source 15, a magnetic field and an electric field may be produced at the coil 13. The alternating electric power may be a RF electric power. Even though the coil 13 and the upper power source 15 reduce a pressure of the process space 1h, plasma having high concentration may be generated.

Referring to FIG. 5, the stage 7 may include a chuck 71 and a cooling plate 73.

The substrate W may be disposed on the chuck 71. The substrate W may contact the chuck 71. The chuck 71 may rigidly place the substrate W on a certain position. The chuck 71 may include a chuck body 711, a plasma electrode 713, a chuck electrode 715, and a heater 717.

The chuck body 711 may have a cylindrical shape. The chuck body 711 may include a ceramic, but the present inventive concepts are not limited thereto. The substrate W may be disposed on a top surface of the chuck body 711. An edge ring ER may surround the chuck body 711. In example embodiments, the edge ring ER may contact a side surface of the chuck body 711.

The plasma electrode 713 may be positioned in the chuck body 711. For example, the chuck body 711 may surround upper, lower, and side surfaces of the plasma electrode 713. The plasma electrode 713 may be formed of or include aluminum (Al). The plasma electrode 713 may have a disk shape, but the present inventive concepts are not limited thereto. An alternating electric power may be applied to the plasma electrode 713. For example, the lower RF power source 4 may apply the alternating electric power to the plasma electrode 713. The lower RF power source 4 may apply a RF electric power to the plasma electrode 713. The alternating electric power applied from the plasma electrode 713 may control the plasma in the process space 1h.

The chuck electrode 715 may be positioned in the chuck body 711. For example, the chuck body 711 may surround upper, lower, and side surfaces of the chuck electrode 715. The chuck electrode 715 may be positioned higher than the plasma electrode 713. The chuck electrode 715 may be positioned between the plasma electrode 713 and the substrate W. A DC electric power may be applied to the chuck electrode 715. For example, the DC power source 2 may apply the DC electric power to the chuck electrode 715. The DC electric power applied from the chuck electrode 715 may rigidly place the substrate W on a certain position on the chuck body 711. The chuck electrode 715 may be formed of or include aluminum (Al), but the present inventive concepts are not limited thereto.

The heater 717 may be positioned in the chuck body 711. For example, the chuck body 711 may surround the heater 717. The heater 717 may be positioned between the chuck electrode 715 and the plasma electrode 713. The heater 717 may include a hot wire. For example, the heater 717 may include a concentrically circular shaped hot wire. The heater 717 may radiate heat to the surrounding environment. Therefore, the chuck body 711 may have an increased temperature.

The cooling plate 73 may be positioned below the chuck 71. For example, the chuck 71 may be positioned on the cooling plate 73. The chuck 71 may contact the cooling plate 73. The cooling plate 73 may provide one or more cooling holes 73h. Cooling water may flow in the one or more cooling holes 73h. The cooling water in the one or more cooling holes 73h may absorb heat from the cooling plate 73.

The dielectric layer 91 may separate the process space 1h. The dielectric layer 91 may be positioned in the process space 1h. The dielectric layer 91 may be disposed upwardly spaced apart from the stage 7. For example, the dielectric layer 91 may be disposed above the stage 7 and may be spaced apart from the stage 7. The process space 1h may include a first process space 1ha above the dielectric layer 91. A top surface of the dielectric layer 91 may define a bottom surface of the first process space 1ha. The process space 1h may include a second process space 1hb below the dielectric layer 91. A bottom surface of the dielectric layer 91 may define a top surface of the second process space 1hb. The first process space 1ha and the second process space 1hb may be divided by the dielectric layer 91. The first process space 1ha may have a height of about 3 mm to about 10 mm. As shown in FIG. 2, an edge of the dielectric layer 91 may be sealed in an inner surface of the process chamber 1. For example, the edge of the dielectric layer 91 may contact the inner surface of the process chamber 1. The edge of the dielectric layer 91 may be sealed in an outer surface of the gas spray device 3. For example, the edge of the dielectric layer 91 may contact the outer surface of the gas spray device 3. The dielectric layer 91 may connect the gas spray device 3 and the process chamber 1 to each other. The first process space 1ha may be sealed by the dielectric layer 91 and the process chamber 1. The first process space 1ha may be in a vacuum state. The dielectric layer 91 may be located at a level higher than that of a lower end of the gas spray device 3. The level of the dielectric layer 91 may be higher than a level of a bottom surface of the gas spray device 3.

The dielectric layer 91 may be connected to the piezoelectric element 93. When a mechanical stress is applied to the piezoelectric element 93, a voltage may be generated from the piezoelectric element 93. In contrast, when a voltage is applied to the piezoelectric element 93, mechanical deformation may occur in the piezoelectric element 93. The piezoelectric element 93 may be formed of or include one or more of quartz, tourmaline, Rochelle salt, barium titanate, and monoammonium phosphate. The present inventive concepts, however, are not limited thereto, and the piezoelectric element 93 may further include one or more materials that undergo mechanical deformation when voltage is applied. The dielectric layer 91 may vibrate due to mechanical deformation occurring when voltage is applied to the piezoelectric element 93. The piezoelectric element 93 may vibrate the dielectric layer 91. The piezoelectric element 93 may be positioned on the dielectric layer 91. The piezoelectric element 93 may be positioned in the first process space 1ha. The piezoelectric element 93 may be electrically connected to the piezo power source 95. The piezo power source 95 may supply the piezoelectric element 93 with an alternating electric power. The alternating electric power of the piezo power source 95 may vibrate the piezoelectric element 93. The vibration of the piezoelectric element 93 may cause vibration of the dielectric layer 91.

Referring to FIGS. 6 and 7, there are provided graphs showing a variation in current in accordance with time of the piezo power source 95, the upper power source 15, and the lower RF power source 4. In each graph, a horizontal axis may denote time. In each graph, a vertical axis may denote intensity and amplitude of current. An alternating current supplied from the piezo power source 95 may have a frequency the same as that of a RF current supplied from the lower RF power source 4. The same frequency may be given to the alternating current of the piezo power source 95, the RF current of the lower RF power source 4, and the alternating current of the upper power source 15. Different amplitudes may be given to the alternating current of the piezo power source 95, the RF current of the lower RF power source 4, and the alternating current of the upper power source 15. For example, the alternating current supplied from the piezo power source 95 may have the same period as that of the RF current supplied from the lower RF power source 4. The dielectric layer 91 may vibrate with a period the same as that of vibration of the piezoelectric element 93. The dielectric layer 91 may have the same frequency as that of the RF current of the lower RF power source 4. A volume of the first process space 1ha may be changed with a period the same as that of vibration of the dielectric layer 91. A volume of the second process space 1hb may be changed with a period the same as that of vibration of the piezoelectric element 93. As the volume of the second process space 1hb is changed, the substrate processing apparatus SY may accelerate the radicals. The acceleration of the radicals may adjust reactivity between the plasma and the substrate W. For example, the acceleration of the radicals may reduce an incidence angle of the radicals. The acceleration of the radicals may induce about 5 percent to about 10 percent increase in etch rate. The acceleration of the radicals may induce about 7 percent increase in etch rate. The etch rate may indicate an etching depth per hour. The acceleration of the radicals may induce about 5 percent to about 15 percent increase in etching depth of the substrate W. The acceleration of the radicals may induce about 10 percent increase in etching depth of the substrate W.

An inner surface of the process chamber 1 may be coated in preparation for falling of particles from the inner surface of the process chamber 1 caused by the dielectric layer 91. For example, a wafer-less auto cleaning (WAC) process may be performed. In the WAC process, oxygen (O₂) plasma may eliminate impurities attached to the inner surface of the process chamber 1. The inner surface of the process chamber 1 may be coated with SiO₂ by using SiCl₄ and O₂ plasma. When the inner surface of the process chamber 1 is coated with SiO₂, the substrate W may be prevented from being contaminated with particles on the inner surface of the process chamber 1. After a process is performed on the substrate W, the WAC process may be used to clean the inner surface of the process chamber 1.

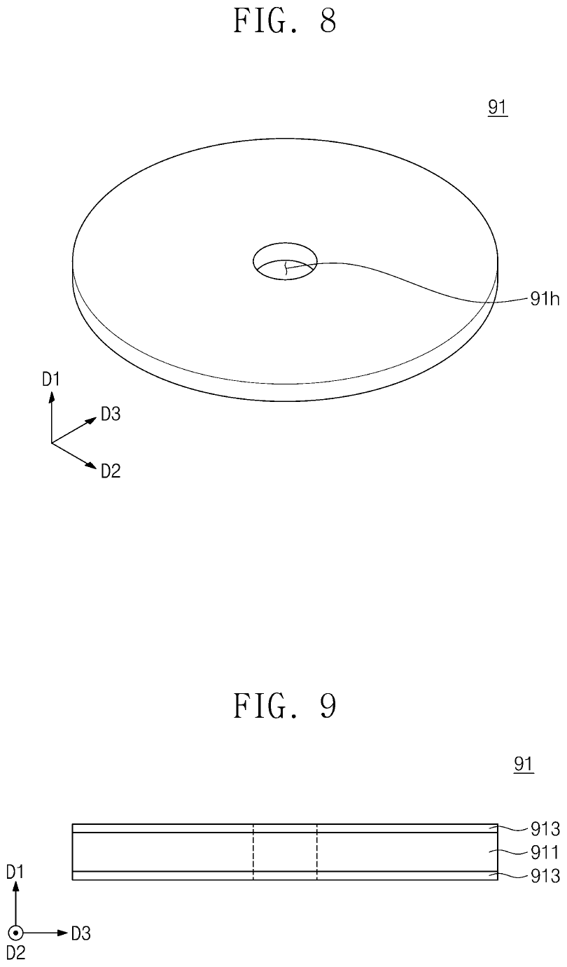

FIG. 8 illustrates a perspective view showing the dielectric layer 91 according to some example embodiments of the present inventive concepts. FIG. 9 illustrates a front view showing the dielectric layer 91 according to some example embodiments of the present inventive concepts.

Referring to FIGS. 8 and 9, the dielectric layer 91 may have a thin film shape. The dielectric layer 91 may provide a through hole 91h. The through hole 91h may be provided in plural. For example, there may be one or more through holes 91h extending through the dielectric layer 91. For convenience, a single through hole 91h will be discussed in this specification, although the description may be applied to any of the one or more through holes 91h. The gas spray device 3 may penetrate the through hole 91h. The dielectric layer 91 of FIGS. 8 and 9 may be the dielectric layer 91 of FIGS. 3 and 4. The dielectric layer 91 may include a film body 911 and a coating layer 913. The film body 911 may include a metallic material. For example, the film body 911 may be formed of or include aluminum (Al), iron (Fe), or copper (Cu). The present inventive concepts, however, are not limited thereto. The coating layer 913 may surround a surface of the film body 911. For example, the coating layer 913 may contact upper and lower surfaces of the film body 911. In example embodiments, the coating layer 913 may contact an entire upper surface and an entire lower surface of the film body 911. The coating layer 913 may include a dielectric material. For example, the coating layer 913 may be formed of or include yttrium oxide (Y₂O₃). The present inventive concepts, however, are not limited thereto. The coating layer 913 may further include any other dielectric material.

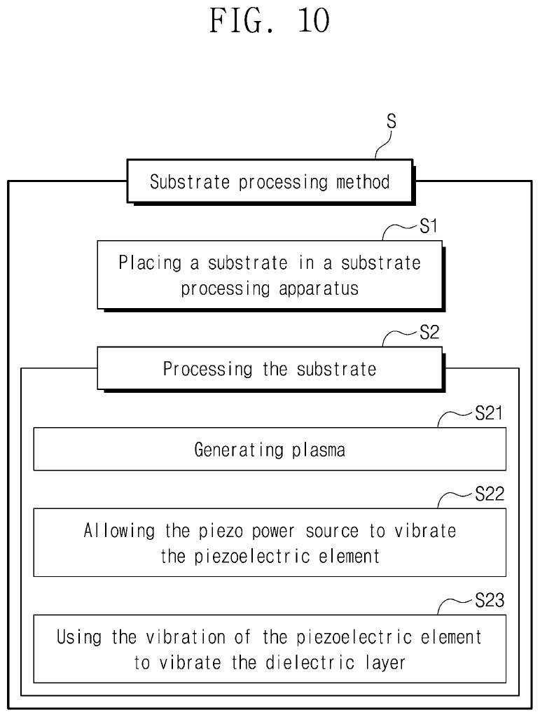

FIG. 10 illustrates a flow chart showing a substrate processing method S according to some example embodiments of the present inventive concepts.

Referring to FIG. 10, the substrate processing method S may include placing the substrate W in the substrate processing apparatus SY (S1) and processing the substrate W (S2). The substrate processing step S2 may include generating plasma (S21), allowing the piezo power source 95 to vibrate the piezoelectric element 93 (S22), and allowing the vibration of the piezoelectric element 93 to vibrate the dielectric layer 91 (S23).

The substrate W may be a bare substrate on which a semiconductor circuit may be formed in later steps of processes. Alternatively, the W may be a substrate on which a semiconductor circuit is already formed. After removing the substrate W from the substrate processing apparatus SF and/or performing additional processes completing semiconductor circuits on the substrate W, the substrate W may be divided into a plurality of semiconductor chips, and the semiconductor chips may be packaged to form semiconductor devices.

According to a substrate processing apparatus and a substrate processing method using the same in accordance with the present inventive concepts, a volume of a second process space may be adjusted to accelerate radicals. A process space may have a constant volume. A volume of a first process space may be changed according to vibration of a dielectric layer. The volume of the second process space may be changed according to vibration of the dielectric layer. A plasma may be present in the second process space. The plasma may include ions and radicals. The change of the volume of the second process space may accelerate plasma particles. For example, the change of the volume of the second process space may accelerate the radicals. The radicals may be controlled to adjust reactivity between the plasma and a substrate. As the radicals are accelerated, only an etch-target layer may be etched deeper.

According to a substrate processing apparatus and a substrate processing method using the same in accordance with the present inventive concepts, an alternating electric power of a piezo power source may be controlled to adjust reactivity between plasmas and a substrate. An alternating current power of the piezo power source may have the same period as that of a RF electric power of an upper power source and that of a RF electric power of a lower RF power source. An alternating current of the piezo power source may have an amplitude different from that of a RF current of the upper power source and a RF current of the lower RF power source. The amplitude of the alternating current of the piezo power source may induce a change in vibration amplitude of a dielectric layer. The vibration amplitude of the dielectric layer may cause a change in acceleration of plasma ions. The vibration amplitude of the dielectric layer may cause a change in acceleration of radicals.

According to a substrate processing apparatus of the present inventive concepts and a substrate processing method using the same, radicals may be accelerated to improve reaction occurring at deep portions of patterns.

According to a substrate processing apparatus of the present inventive concepts and a substrate processing method using the same, radicals may be accelerated to achieve a process with high aspect ratio and high etch selectivity in a semiconductor etching process.

According to a substrate processing apparatus of the present inventive concepts and a substrate processing method using the same, a piezoelectric element and a dielectric plate may be used to change a volume of a process space in which plasma is generated.

According to a substrate processing apparatus of the present inventive concepts and a substrate processing method using the same, a volume of a process space may be changed to accelerate radicals to accomplish a selective etching process.

Effects of the present inventive concepts are not limited to the mentioned above, other effects which have not been mentioned above will be clearly understood to those skilled in the art from the following description.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A substrate processing apparatus, comprising:
a process chamber configured to provide a process space;
a stage configured to support a substrate;
a gas spray device in the process space and upwardly spaced apart from the stage;
a dielectric layer in the process space and upwardly spaced apart from the stage;
a piezoelectric element connected with the dielectric layer and configured to vibrate the dielectric layer; and
a piezo power source configured to supply the piezoelectric element with an alternating electric power.

2. The apparatus of claim 1, further comprising:
a plasma electrode configured to generate plasma and disposed within the stage; and
a lower radio-frequency (RF) power source configured to supply the plasma electrode with an RF electric power.

3. The apparatus of claim 1, wherein the process space includes:
a first process space above the dielectric layer; and
a second process space below the dielectric layer.

4. The apparatus of claim 3,
wherein an edge of the dielectric layer is sealed in an inner surface of the process chamber, and
wherein the first process space is sealed by the dielectric layer and the process chamber.

5. The apparatus of claim 2, wherein a frequency of the RF electric power supplied from the lower RF power source is in a range of about 12 MHz to about 14 MHz.

6. The apparatus of claim 2, wherein an alternating electric power supplied from the piezo power source has a period the same as a period of the RF electric power supplied from the lower RF power source.

7. The apparatus of claim 1,
wherein the piezoelectric element is vibrated with the alternating electric power, and
wherein the dielectric layer is vibrated with a period the same as a period of vibration of the piezoelectric element.

8. The apparatus of claim 1, wherein the dielectric layer includes:
a film body; and
a coating layer that surrounds a surface of the film body,
wherein the coating layer includes yttrium oxide (Y₂O₃).

9. The apparatus of claim 1, wherein a level of the dielectric layer is higher than a level of a lower end of the gas spray device.

10. The apparatus of claim 3, wherein a height of the first process space is in a range of about 3 mm to about 10 mm.

11. A substrate processing apparatus, comprising:
a process chamber configured to provide a process space;
a stage disposed in the process space and configured to support a substrate;
a gas spray device in the process space and upwardly spaced apart from the stage;
a dielectric layer disposed in the process space and having a level higher than a level of a lower end of the gas spray device;
a piezoelectric element connected to and positioned on the dielectric layer; and
a piezo power source configured to supply the piezoelectric element with an alternating electric power,
wherein the dielectric layer includes:
a film body; and
a coating layer which surrounds the film body and includes a dielectric material.

12. The apparatus of claim 11,
wherein a top surface of the dielectric layer defines a bottom surface of a first process space in which the piezoelectric element is disposed, and
wherein a bottom surface of the dielectric layer defines a top surface of a second process space in which the stage is disposed.

13. The apparatus of claim 12,
wherein the first process space and the second process space are separated by the dielectric layer, and
wherein the first process space is in a vacuum state.

14. The apparatus of claim 11, wherein the dielectric layer vibrates with a frequency the same as a frequency of vibration of the piezoelectric element.

15. The apparatus of claim 12, wherein a volume of the second process space is changed with a period the same as a period of vibration of the piezoelectric element.

16. A substrate processing method, comprising:
placing a substrate in a substrate processing apparatus; and
processing the substrate,
wherein the substrate processing apparatus includes:
a process chamber providing a process space;
a gas spray device disposed in the process space and configured to spray a gas into the process space;
a dielectric layer which connects the gas spray device and the process chamber to each other;
a piezoelectric element which is connected to the dielectric layer and is capable of vibrating; and
a piezo power source which supplies the piezoelectric element with an alternating electric power to vibrate the piezoelectric element,
wherein processing the substrate includes:
generating plasma;
allowing the piezo power source to vibrate the piezoelectric element; and
using the vibration of the piezoelectric element to vibrate the dielectric layer.

17. The method of claim 16, wherein the substrate processing apparatus further includes:
a stage which supports the substrate and is positioned in the process space; and
a lower radio-frequency (RF) power source which has an electrical connection with the stage and generates the plasma.

18. The method of claim 17, wherein a frequency of a RF electric power supplied from the lower RF power source is the same as a frequency of the dielectric layer.

19. The method of claim 16, wherein a level of a lower end of the gas spray device is lower than a level of the dielectric layer.

20. The method of claim 16,
wherein a top surface of the dielectric layer defines a bottom surface of a first process space in which the piezoelectric element is positioned, and
wherein the first process space is sealed by the process chamber and the dielectric layer.
